(19) United States
(12) Patent Application Publication
(10) Pub. No.: US 2010/0304789 A1
(43) Pub. Date: Dec. 2, 2010

(54) METHOD FOR SCANNING FREQUENCIES, TUNER, DVB-H RECEIVER COMPRISING THE TUNER, AND MOBILE PHONE COMPRISING THE DVB-H RECEIVER

(75) Inventors: Guillaume Defoug, Paris (FR); Joseph Antunes, Palaiseau (FR)

Correspondence Address: YOUNG & THOMPSON, 209 Madison Street, Suite 500, Alexandria, VA, 22314, US

(73) Assignee: DIBCOM, Palaiseau (FR)

(21) Appl. No.: 12/809,215

(22) PCT Filed: Dec. 22, 2008
(86) PCT No.: PCT/EP2008/068131

§ 371 Date: Jun. 18, 2010

(30) Foreign Application Priority Data
Dec. 21, 2007 (EP) 07291608.3

(51) Int. Cl. H04W 88/02; H04N 7/16; H03J 3/00

(52) U.S. Cl. 455/556.1; 725/151; 334/89

(57) ABSTRACT

A method for scanning frequencies of a network by a tuner, in order to determine available frequencies, the network including a plurality of coverage zones, a respective signal being emitted over each coverage zone of the network, at a respective frequency, the tuner being located in one of the coverage zones, referred to as the current coverage zone, a signal, referred to as the current signal, being emitted over the current coverage zone, the current signal conveying a plurality of services according to a time slicing method. The method includes obtaining a group of frequency values of the frequencies of coverage zones of the network, and during time intervals separating the time slices dedicated to the at least one service intended to be received, the tuner scanning all the frequency values of the group in order to determine available frequencies, whatever is the number of frequency values in the group.

A lot of present mobile phones comprise a DVB-H receiver for receiving services, in particular video services. A DVB-H receiver comprises a tuner and a demodulator.

A DVB-H network comprises a plurality of coverage zones (also called coverage cells), with most of the coverage zones overlapping with neighbor coverage zones.

A respective signal is emitted over each coverage zone, at a respective frequency.

Each signal conveys a plurality of services by using a time slicing method, so that one particular service is not transmitted continuously, but in periodical time slices (or bursts). A same service is typically conveyed by several signals of different coverage zones, so that the service can be received on a broad area.

In operation, the tuner is located in one of the coverage zones, referred to as the current coverage zone, the current coverage zone emitting a signal, referred to as the current signal. The tuner is synchronized with the current signal during the time slices dedicated to the at least one service intended to be received, leaving free the time intervals separating the time slices dedicated to the at least one service intended to be received.

In order for the receiver to move to another coverage zone without service interruption, it is known to scan the frequencies of the network. The known scanning method comprises obtaining a group of frequency values of the frequencies of coverage zones of the network, and start periodically a scan of the frequency values of the group, with a predetermined fixed periodicity. The time between two starts of scan is thus also fixed and called the monitoring time.

However, the number of frequency values of the group may change in time, so that two main problems occur.

First, in the case the group happen to comprise a lot of frequency values, the tuner will not have the time to scan all the frequency values of the group during the monitoring time, so that some frequency values of the group will not be scanned.

Second, in the case the group happen to comprise few frequencies, the tuner will end the scan very quickly, leaving the rest of the monitoring time unused.

The invention aims at alleviating the previous problems, with a method for scanning frequencies that does not need a fixed monitoring time.

Accordingly, the invention relates to a method according to claim 1.

Other features of the method are set forth in dependant claims 2 to 6.

The invention further relates to a tuner according to claim 7.

Other features of the tuner are set forth in claims 8 to 11.

The invention further relates to a receiver according to claim 12.

The invention further relates to a mobile phone according to claim 13.

These features and other of the invention will become apparent by reading the following description of an embodiment of the invention. The description refers to the enclosed drawings, which comprise:

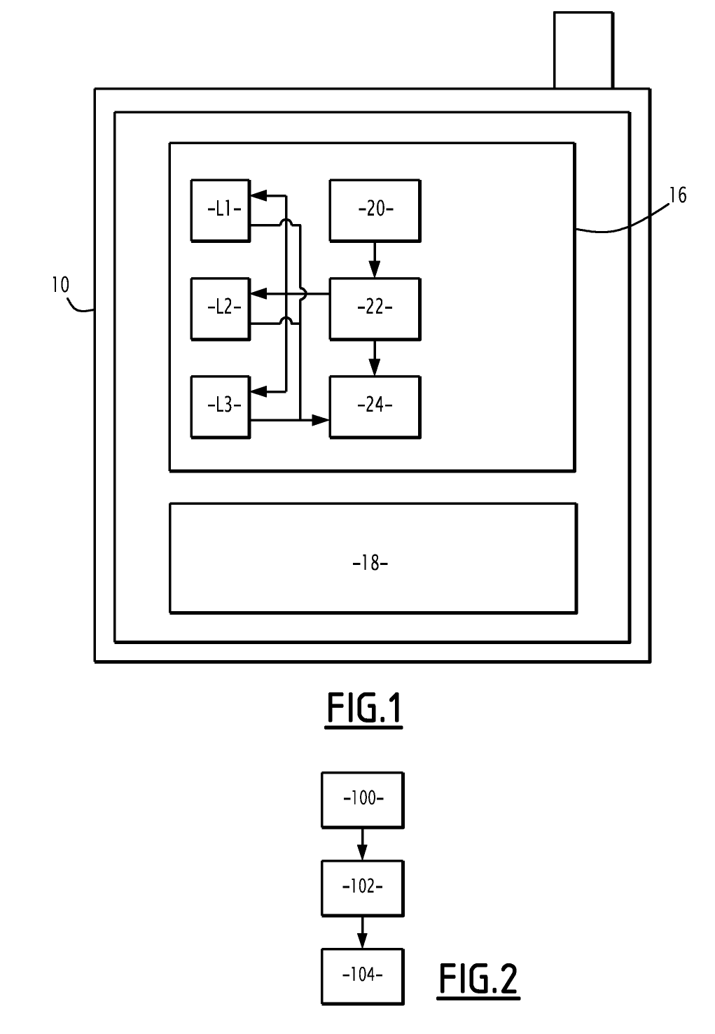

FIG. 1: a mobile phone comprising a receiver according to the invention,

FIG. 2: a bloc-diagram of a method for scanning frequencies, achieved by the receiver of FIG. 1, and

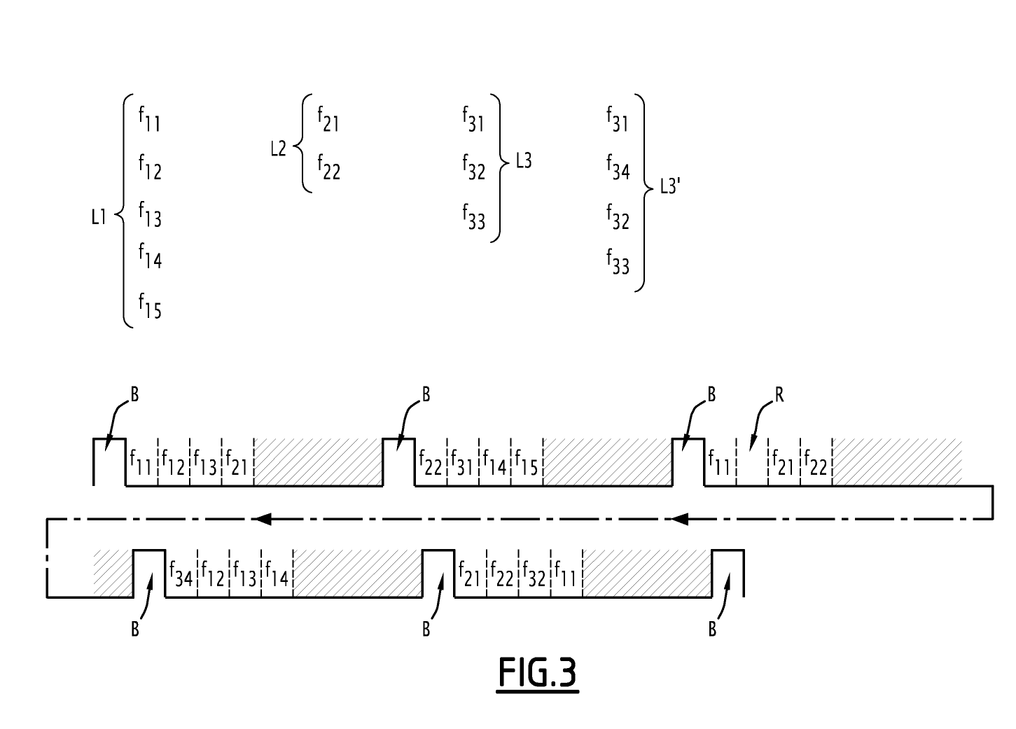

FIG. 3: a time line illustrating a frequency scanning according to the method of FIG. 2.

Referring to FIG. 1, a mobile phone 10 comprises a DVB-H receiver 12.

The DVB-H receiver 12 comprises a tuner 16 and a demodulator 18.

The tuner 16 is configured for synchronizing to a DVB-H signal emitted at a respective frequency, and for scanning frequency values, in order to determine available frequencies.

The demodulator 18 is configured for demodulating the signal to which the tuner is synchronized, in order to allow the terminal to display to the user at least one service conveyed by the signal.

The tuner 16 comprises a module 20 for obtaining all the frequency values of the frequencies of the coverage zones of the network, excluding the current coverage zone.

More precisely, the module 20 is configured for obtaining the frequency values from SI/PSI tables conveyed in the DVB-H signal to which the tuner 16 is synchronized.

The tuner 16 further comprises a memory in which at least one list of frequency values is stored. In FIG. 1, three lists L1, L2, L3 are illustrated.

The tuner 16 further comprises a module 22 for classifying the frequency values obtained by the module 20 in groups of frequency values, one group for each list. This means that the module 20 is intended to determined, for each obtained frequency value, the group it belongs to. The module 20 is further intended to update the at least one list according to the classification (by removing and/or adding frequency values to the list).

The tuner 16 further comprises a module 24 for continuously scanning the frequency values of the at least one group, in a way that will be further described in the following description, with reference to FIG. 2. Scanning a frequency value means to try to synchronize the tuner 16 on the frequency values, in order to determine if the frequency is available. The modules 22 and 24 are intended to function in parallel. Ther module 24 is configured for scanning only one frequency value at a time.

Referring to FIG. 2, a method for scanning frequencies of a network, achieved by the tuner 16 of FIG. 1, will now be explained.

The network comprises a plurality of coverage zones, a respective DVB-H signal being emitted over each coverage zone of the network, at a respective frequency.

Each DVB-H signal conveys a plurality of services according to a time slicing method, so that each service is conveyed during a periodical time slice dedicated to the service.

The mobile phone 10, and thus also the tuner 16, is located in one of the coverage zones, referred to as the current coverage zone. A DVB-H signal, referred to as the current signal, is emitted over the current coverage zone.

The current signal is received by the receiver 12, so as to receive at least one service conveyed by the current signal. More precisely, the tuner is synchronized with the current signal during the time slices dedicated to the at least one service being received, while the demodulator 18 demodulates the time slices dedicated to the at least one service being received.

The method first comprises the module 20 obtaining (step 100) all the frequency values of the frequencies of the coverage zones of the network.

The method then comprises the module 22 classifying (step 102) the obtained frequencies in three groups, and updating the three lists L1, L2, L3 accordingly.

The first group regroups the frequency values of the frequencies of the signals, each being emitted over a coverage zone that overlaps with the current coverage zone, and each conveying the same content as the current signal. The first group is further associated with a first weight. The frequency values of the first group are listed in the first list L1.

The second group regroups the frequency values of the frequencies of the signals, each emitted over a coverage zone that does not overlap with the current coverage zone, and each conveying the same content as the current signal. The second group is further associated with a second weight. The frequency values of the second group are listed in the second list L2.

The third group regroups the frequency values of the frequencies of the signals, conveying a content that is different from the content of the current signal. The third group is further associated with a third weight. The frequency values of the third group are listed in the third list L3.

In the previous definitions of the group, “content” means “the service or services that the mobile phone 10 receives through the current DVB-H signal”, a service being identified by its IP address and platform ID.

The first, second and third weights are set by the network. For instance, the mobile phone 10 acquires them through the received current signal. Preferably, at least one of the three weights is different from the other.

The method further comprises, during time intervals separating the time slices dedicated to the at least one service being received, the tuner 16 scanning (step 104) all the frequency values of each group, whatever is the number of frequency value in the preceding group. More precisely, the module 24 browses continuously each list L1, L2, L3, in a loop manner, i.e. from the beginning to the end of the list, then back to the beginning. The scanning is realised in parallel to the updating of the lists L1, L2, L3.

Preferably, the scanning of the groups are mixed up: the tuner 16 scans some frequency values of the first group, then some frequency values of the second group, then some frequency values of the third group, then some frequency values of the first group again, etc. More precisely, the ratio between the number of times one of the groups is scanned and the number of times another of the groups is scanned is equal to the ratio of their respective weights.

In a first embodiment, the tuner 16 is configured for scanning during all the time intervals separating the time slices dedicated to the at least one service being received.

In a second embodiment, the tuner 16 is configured for scanning the frequency values only during a ratio of the time intervals separating the time slices dedicated to the at least one service intended to be received.

Preferably, the ratio is set by the network, through the received current signal.

Preferably, the module 20 is intended to update each list by adding new frequency values after the currently scanned frequency value (or the last frequency value that has been scanned if the module 24 is scanning the frequency value of another list), near the currently scanned frequency value, for example 10 or less frequency values ahead from the currently scanned frequency value. In this way, the new added frequency values are scanned a short time after their addition.

FIG. 3 illustrates scanning of the frequency values of the lists L1, L2, L3 when L1 has a weight of 3, L2 has a weight of 2, L3 has a weight of 1, and with a scanning ratio of 50%. The time slices dedicated to the at least one service being received are indicated with the reference B. At the instant R, the list L3 is updated by the module 22 so as to give an updated list L3′ where the frequency value f₃₄ is added, just after the last scanned frequency of the list L3, i.e. f₃₁.

1. Method for scanning frequencies of a network by a tuner (16), in order to determine available frequencies,
the network comprising a plurality of coverage zones,
a respective signal being emitted over each coverage zone of the network, at a respective frequency,
the tuner (16) being located in one of the coverage zones, referred to as the current coverage zone, a signal, referred to as the current signal, being emitted over the current coverage zone,
the current signal conveying a plurality of services according to a time slicing method, so that each service is conveyed during a periodical time slice dedicated to the service,
the tuner (16) being synchronized with the current signal during the time slices dedicated to the at least one service intended to be received,
the method comprising:
obtaining (100, 102) a group of frequency values of the frequencies of coverage zones of the network,
the method being characterized by:
during time intervals separating the time slices dedicated to the at least one service intended to be received, the tuner (16) scanning (104) all the frequency values of the group in order to determine available frequencies, whatever is the number of frequency values in the group.

2. Method according to claim 1, further characterized by:
obtaining (100) all the frequency values of the frequencies of the coverage zones of the network,
classifying (102) the obtained frequency values in at least two groups of frequency values,
during time intervals separating the time slices dedicated to the at least one service intended to be received, the tuner (16) scanning (104) all the frequency values of each group in order to determine available frequencies, whatever is the number of frequency values in each group.

3. Method according to claim 2, characterized in that:
each of the groups is associated with a respective weight,
at least one of the weights is different from the other weights,
each group is scanned a number of times, the number of times each group is scanned corresponding to its associated weight, so that the ratio between the number of times one of the groups is scanned and the number of times another of the groups is scanned is equal to the ratio of their respective weights.

4. Method according to claim 2, further characterized in that the at least two groups of frequency values comprise:
a first group regrouping the frequency values of the frequencies of the signals:
emitted over a coverage zone that overlaps with the current coverage zone, and
conveying the same content as the current signal,
a second group regrouping the frequency values of the frequencies of the signals:
emitted over a coverage zone that does not overlap with the current coverage zone, and
conveying the same content as the current signal, and
a third group regrouping the frequency values of the frequencies of the signals:
conveying a content that is different from the content of the current signal.

5. Method according to claim 1, further characterized in that the scanning of frequency values is achieved only during a ratio of the time intervals separating the time slices dedicated to the at least one service intended to be received.

6. Method according to claim 1, further characterized in that:
the network is a DVB-H network,
the signals emitted over the coverage zones of the network are DVB-H signals, and
obtaining of frequency values is realized from SI/PSI tables conveyed in the current DVB-H signal.

7. Method according to claim 1, further characterized by:
each group is associated with a list (L1, L2, L3) regrouping the frequency values of the group;
updating the at least one list (L1, L2, L3);
the tuner (16) scanning (104) all the frequency values of the group comprises browsing continuously each list (L1, L2, L3), in a loop manner, i.e. from the beginning to the end of the list, then back to the beginning.

8. Tuner (16) for scanning frequencies of a network, in order to determine available frequencies
the network comprising a plurality of coverage zones,
a respective signal being emitted over each coverage zone of the network, at a respective frequency,
the tuner (16) being intended to be located in one of the coverage zones, referred to as the current coverage zone, a signal, referred to as the current signal, being emitted over the current coverage zone,
the current signal conveying a plurality of services according to a time slicing method, so that each service is conveyed during a periodical time slice dedicated to the service,
the tuner (16) being configured for synchronizing with the current signal during the time slices dedicated to the at least one service intended to be received,
the tuner (16) comprising:
means (20, 22) for obtaining a group of frequency values of the frequencies of coverage zones of the network,
the tuner (16) being characterized in that it is configured for, during time intervals separating the time slices dedicated to the at least one service intended to be received, scanning all the frequency values of the group in order to determine available frequencies, whatever is the number of frequency values in the group.

9. Tuner (16) according to claim 8, characterized in that the means (20, 22) for obtaining a group of frequency values comprise:
a module (20) for obtaining all the frequency values of the frequencies of the coverage zones of the network,
a module (22) for classifying the obtained frequency values in at least two groups of frequency values,
and in that the tuner (16) is configured for, during time intervals separating the time slices dedicated to the at least one service intended to be received, scanning all the frequency values of each group in order to determine available frequencies, whatever is the number of frequency values in each group.

10. Tuner (16) according claim 9, characterized in that the module (22) for classifying the obtained frequency values is configured for classifying the obtained frequency values in three groups:
a first group regrouping the frequency values of the frequencies of the signals:
emitted over a coverage zone that overlaps with the current coverage zone, and
conveying the same content as the current signal,
a second group regrouping the frequency values of the frequencies of the signals:
emitted over a coverage zone that does not overlap with the current coverage zone, and
conveying the same content as the current signal, and
a third group regrouping the frequency values of the frequencies of the signals:
conveying a content that is different from the content of the current signal.

11. Tuner (16) according to claim 8, characterized in that the tuner (16) is configured for scanning frequency values only during a ratio of the time intervals separating the time slices dedicated to the at least one service intended to be received.

12. Tuner (16) according to claim 8, further characterized in that, the network being a DVB-H network, and the signals emitted over the coverage zones of the network being DVB-H signals, the means (20, 22) for obtaining frequency values are configured for obtaining the frequency values from SI/PSI tables conveyed in the current DVB-H signal.

13. Tuner (16) according to claim 8, further characterized by:
at least one list (L1, L2, L3), each associated with a respective group and regrouping the frequency values of the group;
a module (22) for updating the at least one list (L1, L2, L3);
a module (24) for browsing continuously each list (L1, L2, L3), in a loop manner, i.e. from the beginning to the end of the list, then back to the beginning.

14. DVB-H receiver (12) comprising a tuner (16) according to claim 8, and a demodulator (18) for demodulating the current signal.

15. Mobile phone (10) comprising a DVB-H receiver according to claim 14.
